(19) United States
(12) Patent Application Publication
(10) Pub. No.: US 2019/0378967 A1
(43) Pub. Date: Dec. 12, 2019

(54) FLEXIBLE THERMOELECTRIC CONVERSION ELEMENT AND METHOD FOR MANUFACTURING SAME

(71) Applicant: LINTEC CORPORATION, Itabashi-ku (JP)

(72) Inventors: Wataru MORITA, Saitama-shi (JP); Kunihisa KATO, Warabi-shi (JP); Tsuyoshi MUTOU, Saitama-shi (JP); Takeshi KONDO, Saitama-shi (JP)

(73) Assignee: LINTEC CORPORATION, Itabashi-ku (JP)

(21) Appl. No.: 16/480,141

(22) PCT Filed: Jan. 24, 2018
(86) PCT No.: PCT/JP2018/002065

§ 371 Date: Jul. 23, 2019

(30) Foreign Application Priority Data
Jan. 27, 2017 (JP) 2017-013006

(51) Int. Cl. H01L 35/34; H01L 35/30; C09J 7/38; H02N 11/00

(52) U.S. Cl. CPC H01L 35/34; H02N 11/00; C09J 7/38; H01L 35/30

(57) ABSTRACT

Provided are a flexible thermoelectric conversion device having high thermoelectric performance and capable of imparting a sufficient temperature difference in an in-plane direction to the thermoelectric elements inside the thermoelectric conversion module therein, and a method for producing the device. The flexible thermoelectric conversion device includes a thermoelectric conversion module having P-type thermoelectric elements and N-type thermoelectric elements alternately arranged to be adjacent to each other on one face of a film substrate, and includes a high thermally conductive layer composed of a high thermally conductive material in a part of a position on one face of the thermoelectric conversion module, which is on the side of the other face of the film substrate, among both faces of the thermoelectric conversion module, in which the thermal conductivity of the high thermally conductive layer is 5 to 500 (W/m·K), and the production method produces the device.

### TECHNICAL FIELD

The present invention relates to a flexible thermoelectric conversion device using a thermoelectric conversion material that carries out energy interconversion between heat and electricity.

### BACKGROUND ART

Heretofore, there are known a thermoelectric power generation technology and a Peltier cooling technology as an energy conversion technology using thermoelectric conversion. A thermoelectric power generation technology is a technology that utilizes conversion of heat energy to electric energy by a Seebeck effect, and the technology has attracts lots of attention as an energy-saving technique capable of recovering unused waste heat energy generated from fossil fuel resources and others that are used especially in buildings, factories and others, as electric energy not requiring any additional driving cost. As opposed to this, a Peltier cooling technology is, contrary to thermoelectric power generation, a technology that utilizes conversion of electric energy into heat energy by a Peltier effect, and this technology is used, for example, in parts and devices that require precision temperature control for cooling CPUs for use in wine cooler, small-sized and portable refrigerator and computers, and further for temperature control of optical communication semiconductor laser oscillators and others.

As a thermoelectric conversion device utilizing such thermoelectric conversion, an in-plane-type thermoelectric conversion device is known. An in-plane type is meant to indicate a thermoelectric conversion device that converts heat energy into electric energy by a temperature difference to occur in the in-plane direction of the thermoelectric conversion layer therein but not in the thickness direction of the layer.

Taking installation thereof in waste heat sources or heat dissipators having an uneven face into consideration, thermoelectric conversion devices may be required to be flexible so as not to be limited in point of the installation sites for them.

Patent Literature 1 discloses an in-plane-type flexible thermoelectric conversion device. Specifically, in this, a P-type thermoelectric element and an N-type thermoelectric element are connected in series and a thermoelectric force extraction electrode is arranged at both ends thereof to construct a thermoelectric conversion module, and a flexible film-like substrate formed of two types of materials each having a different thermal conductivity is provided at both faces of the thermoelectric conversion module. The film-like substrate is provided with a material having a low thermal conductivity (polyimide) at the bonding face side to the thermoelectric conversion module, while on the side opposite to the bonding face side to the thermoelectric conversion module, a material having a high thermal conductivity (copper) is arranged so as to be positioned at a part of the outer face of the substrate.

Patent Literature 2 discloses a flexible thermoelectric conversion device that contains a thermally conductive adhesive sheet having high thermally conductive portions and low thermally conductive portions alternately arranged on both faces of an in-plane-type thermoelectric conversion module.

### PATENT LITERATURE

Patent Literature 1: JP 2006-186255 A

Patent Literature 2: WO 2015/046253

### SUMMARY OF INVENTION

### Technical Problem

However, in Patent Literature 1, the high thermally conductive portions are thin for maintaining flexibility and the low thermally conductive portions formed of a resin layer could not have sufficient thermoelectric performance. In Patent Literature 2, a metal filler or the like is incorporated in the resin layer to form the high thermally conductive portions, therefore limiting the temperature difference given to the device.

In consideration of the above-mentioned problems, an object of the present invention is to provide a flexible thermoelectric conversion device having high thermoelectric performance and capable of imparting a sufficient temperature difference in an in-plane direction to the thermoelectric elements inside the thermoelectric conversion module therein, and to provide a method for producing the device.

### Solution to Problem

The present inventors have assiduously made repeated studies for solving the above-mentioned problems and, as a result, have found that, when a high thermally conductive layer composed of a high thermally conductive material having a specific thermal conductivity is formed at a specific position on a part on a face of a thermoelectric conversion module having, as alternately arranged on a film substrate to be adjacent to each other, P-type thermoelectric elements and N-type thermoelectric elements, and when a sufficient temperature difference is given in an in-plane direction thereto, then the above-mentioned problems can be solved, and have completed the present invention.

Specifically, the present invention provides the following (1) to (8);

(1) A flexible thermoelectric conversion device including a thermoelectric conversion module having P-type thermoelectric elements and N-type thermoelectric elements alternately arranged to be adjacent to each other on one face of a film substrate; and a high thermally conductive layer composed of a high thermally conductive material in a part of a position on at least one face of the thermoelectric conversion module, which is on the side of the other face of the film substrate, among both faces of the thermoelectric conversion module, wherein the thermal conductivity of the high thermally conductive layer is from 5 to 500 (W/m·K).
(2) The flexible thermoelectric conversion device according to the above (1), further including the high thermally conductive layer in a part on the face of the thermoelectric conversion module opposite to the face of the thermoelectric conversion module which is on the side of the other face of the film substrate, among both faces of the thermoelectric conversion module.
(3) The flexible thermoelectric conversion device according to the above (1) or (2), wherein the high thermally conductive layer is arranged via a pressure-sensitive adhesive layer.
(4) The flexible thermoelectric conversion device according to any of the above (1) to (3), wherein the thickness of the high thermally conductive layer is from 40 to 550 μm.
(5) The flexible thermoelectric conversion device according to any of the above (1) to (4), wherein the high thermally conductive material is copper or stainless.
(6) The flexible thermoelectric conversion device according to any of the above (1) to (5), wherein the proportion of the high thermally conductive layer positioned is from 0.30 to 0.70 relative to the entire width in the serial direction occupied by a pair of a P-type thermoelectric element and an N-type thermoelectric element.
(7) The flexible thermoelectric conversion device according to any of the above (1) to (6), which satisfies L 0.04R, where L represents a maximum length of the high thermally conductive layer in a direction parallel to the direction of the P-type thermoelectric elements and the N-type thermoelectric elements alternately arranged to be adjacent to each other on the plane of the thermoelectric conversion module; and R represents a minimum radius of curvature in terms of a face on which the thermoelectric conversion module is to be mounted, with the proviso that the minimum radius of curvature is determined as follows: an electric resistance value between output extraction electrodes of the flexible thermoelectric conversion device is measured before and after the flexible thermoelectric conversion device is mounted on a curved face having a known radius of curvature, and a minimum value of the radius of curvature at which the electric resistance increment is 20% or less is designated as the minimum radius of curvature.
(8) A method for producing a flexible thermoelectric conversion device which includes a thermoelectric conversion module having P-type thermoelectric elements and N-type thermoelectric elements alternately arranged on one face of a film substrate to be adjacent to each other, and a high thermally conductive layer composed of a high thermally conductive material in a part on at least the other face of the film substrate among both faces of the thermoelectric conversion module, in which the thermal conductivity of the high thermally conductive layer is from 5 to 500 (W/m·K);

the method including a step of forming P-type thermoelectric elements and N-type thermoelectric elements on one face of the film substrate, and a step of forming a high thermally conductive layer on a part on the other face of the film substrate.

### Advantageous Effects of Invention

According to the present invention, there are provided a flexible thermoelectric conversion device having high thermoelectric performance and capable of imparting a sufficient temperature difference to the in-plane direction of the thermoelectric elements inside the thermoelectric conversion module, and a method for producing the device.

### BRIEF DESCRIPTION OF DRAWINGS

FIG. 1 is a cross-sectional view showing a first embodiment of a flexible thermoelectric conversion device of the present invention.

FIG. 2 is a cross-sectional view showing a second embodiment of a flexible thermoelectric conversion device of the present invention.

FIG. 3 is a plan view showing a configuration of a thermoelectric conversion module used in Examples of the present invention.

### DESCRIPTION OF EMBODIMENTS

### [Flexible Thermoelectric Conversion Device]

The flexible thermoelectric conversion device of the present invention includes a thermoelectric conversion module having P-type thermoelectric elements and N-type thermoelectric elements alternately arranged to be adjacent to each other on one face of a film substrate, and contains a high thermally conductive layer composed of a high thermally conductive material in a part of a position on at least one face of the thermoelectric conversion module, which is on the side of the other face of the film substrate, among both faces of the thermoelectric conversion module, wherein the thermal conductivity of the high thermally conductive layer is 8 to 500 (W/m·K).

The flexible thermoelectric conversion device of the present invention is described with reference to the drawings.

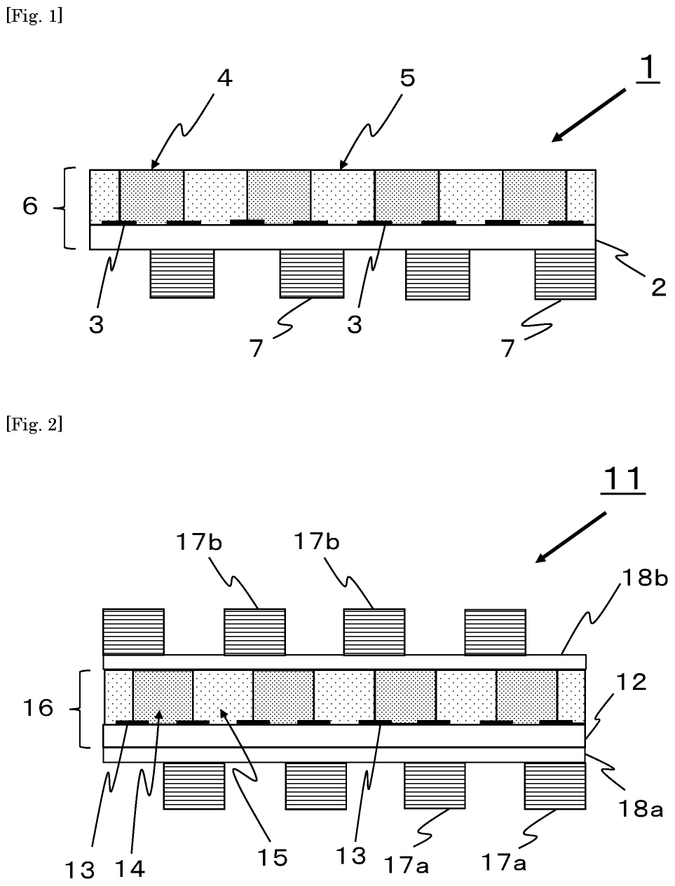

FIG. 1 is a cross-sectional view showing a first embodiment of a flexible thermoelectric conversion device of the present invention. The flexible thermoelectric conversion device 1 is composed of a thermoelectric conversion module 6 including p-type thermoelectric elements 5 and n-type thermoelectric elements 4 formed on one face of a film substrate 2 having electrodes 3 thereon, and a high thermally conductive layer 7 composed of a high thermally conductive material on the other face of the film substrate 2 among both faces of the thermoelectric conversion module 6.

Similarly, FIG. 2 is a cross-sectional view showing a second embodiment of a flexible thermoelectric conversion device of the present invention. The flexible thermoelectric conversion device 11 is composed of a thermoelectric conversion module 16 including P-type thermoelectric elements 15 and N-type thermoelectric elements 14 formed on one face of a film substrate 12 having electrodes 13 thereon, and high thermally conductive layers 17a and 17b composed of a high thermally conductive material formed on both faces of the thermoelectric conversion module 16 each via a pressure-sensitive adhesive layer 18a or 18b.

### <High Thermally Conductive Layer>

The high thermally conductive layer in the present invention is, for example, as shown in FIG. 1, arranged in a part on at least one face of the thermoelectric conversion module, which is on the side of the other face of the film substrate, among both faces of the thermoelectric conversion module having P-type thermoelectric elements and N-type thermoelectric elements alternately arranged to be adjacent to each other, and can radiate heat selectively in a specific direction. Accordingly, a temperature difference can be given to the in-plane direction of the thermoelectric conversion module. Further, from the viewpoint of imparting a larger temperature difference, preferably, the high thermally conductive layer is additionally arranged in a part of a position on the face of the thermoelectric conversion module opposite to the face of the thermoelectric conversion module which is on the side of the other face of the film substrate among both faces of the thermoelectric conversion module, for example, as shown in FIG. 2.

The high thermally conductive layer in the present invention is formed of a high thermally conductive material. A method of forming the high thermally conductive layer is not specifically limited, and an example thereof includes previously patterning the above-mentioned, sheet-like high thermally conductive material into a desired pattern form through known physical treatment or chemical treatment or a combination thereof mainly according to photolithography. Subsequently, it is desirable that the thus-patterned high thermally conductive layer is formed on a thermoelectric conversion module via a pressure-sensitive adhesive layer to be mentioned hereinunder.

Also employable is a method of directly forming a pattern of a high thermally conductive layer according to a screen printing method or an inkjet method.

Further employable is a method of forming an unpatterned high thermally conductive layer composed of a high thermally conductive material according to a dry process of PVD (physical vapor deposition) such as a vacuum evaporation method, a sputtering method or an ion-plating method, or CVD (chemical vapor deposition) of thermal CVD or atomic layer deposition (ALD), or according to a wet process of various coating or electrodeposition methods such as a dip coating method, a spin coating method, a spray coating method, a gravure coating method, a die coating method or a doctor blade coating method, or also a silver salt method, followed by patterning the resultant unpatterned layer into a predetermined pattern form through known physical treatment or chemical treatment or a combination thereof mainly according to photolithography.

In the present invention, from the viewpoint of the constituent materials of the thermoelectric conversion module and the process simplicity, preferably, a sheet-like high thermally conductive material is formed into a predetermined pattern through known chemical treatment mainly according to photolithography, for example, by wet-etching a patterning part of a photoresist followed by removing the photoresist, thereby forming a pattern of the high thermally conductive material on both faces or any face of the thermoelectric conversion module via a pressure-sensitive adhesive layer to be mentioned hereinunder.

Though not specifically limited, the configuration and the shape of the high thermally conductive layer will have to be appropriately controlled depending on the configuration and the shape of the thermoelectric elements, that is, the P-type thermoelectric elements and the N-type thermoelectric elements of the thermoelectric conversion module to be used here.

For example, in the case of the first embodiment, preferably, the proportion of the high thermally conductive layer positioned is 0.30 to 0.70 relative to the entire width in the serial direction occupied by a pair of the P-type thermoelectric element and the N-type thermoelectric element, more preferably 0.40 to 0.60, even more preferably 0.48 to 0.52, and especially preferably 0.50. Falling within the range, heat can be radiated selectively in a specific direction to thereby make it possible to impart a temperature difference efficiently in the in-plane direction. Further preferably, the above is satisfied and in addition, the high thermally conductive layer is arranged symmetrically to the bonding part of a pair of the P-type thermoelectric element and the N-type thermoelectric element in a serial direction. Arranging the high thermally conductive layer in such a manner makes it possible to impart a larger temperature difference between the in-plane bonding part of a pair of a P-type thermoelectric element and an N-type thermoelectric element in a serial direction and the bonding part of another pair of a P-type thermoelectric element and an N-type thermoelectric element adjacent thereto.

Also, for example, in the case of the second embodiment, the high thermally conductive layers to be arranged on both faces are preferably so arranged as not to face each other and so as to be symmetrically to their bonding parts relative to the pair of a P-type thermoelectric element and an N-type thermoelectric element in a serial direction.

The thermal conductivity of the high thermally conductive layer composed of a high thermally conductive material for use in the present invention is 5 to 500 (W/m·K). When the thermal conductivity of the high thermally conductive layer is less than 5, a temperature difference could not be efficiently imparted to the in-plane direction of the thermoelectric conversion module where P-type thermoelectric elements and N-type thermoelectric elements are alternately and electrically connected in series via an electrode therebetween. On the other hand, a high thermally conductive layer having a thermal conductivity of more than 500 (W/m·K) is impracticable from the viewpoint of cost and processability, though diamond or the like may be referred to in point of physical property. Preferably, the thermal conductivity is 8 to 500 (W/m·K), more preferably 10 to 450 (W/m·K), even more preferably 12 to 420 (W/m·K), still more preferably 15 to 420 (W/m·K), especially more preferably 300 to 420 (W/m·K), and most preferably 350 to 420 (W/m·K) When the thermal conductivity falls within the above range, a temperature difference can be imparted efficiently in the in-plane direction of the thermoelectric conversion module.

Examples of the high thermally conductive material include simple metals such as copper, silver, iron, nickel, chromium and aluminum; and alloys such as stainless and brass. Among these, copper (including oxygen-free copper) and stainless are preferred, and as having a high thermal conductivity and easy to process, copper is more preferred.

Specific examples of the high thermally conductive material for use in the present invention are shown below.

### Oxygen-Free Copper

Oxygen-free copper (OFC) is, in general, a high-purity copper not containing any oxide and having a purity of 99.95% (3N) or more. Japanese Industrial Standards define oxygen-free copper (JIS H 3100, C1020) and oxygen-free copper for electronic valves (JIS H 3510, C1011).

### Stainless (JIS)

SUS304; 18Cr-8Ni (stainless steel containing 18% Cr and 8% Ni)

SUS316; 18Cr-12Ni (stainless steel containing 18% Cr, 12% Ni, and molybdenum (Mo))

The thickness of the high thermally conductive layer is preferably 40 to 550 μm, more preferably 60 to 530 μm, and even more preferably 80 to 510 μm. Having a thickness falling within the range, the high thermally conductive layer can selectively radiate heat in a specific direction, therefore efficiently imparting a temperature difference to the in-plane direction of the thermoelectric conversion module where P-type thermoelectric elements and N-type thermoelectric elements are alternately electrically connected in series via electrodes therebetween.

### (Pressure-Sensitive Adhesive Layer)

Preferably, the high thermally conductive layer is arranged via a pressure-sensitive adhesive layer.

An adhesive or a pressure-sensitive adhesive is preferably used as a component to constitute the pressure-sensitive adhesive layer. As the adhesive or the pressure-sensitive adhesive, those having, as a base polymer, any of an acrylic polymer, a silicone polymer, a polyester, a polyurethane, a polyamide, a polyvinyl ether, a vinyl acetate/vinyl chloride copolymer, a modified polyolefin, an epoxy polymer, a fluoropolymer or a rubber polymer may be appropriately selected and used. Among these, a pressure-sensitive adhesive having an acrylic polymer as a base polymer, and a pressure-sensitive adhesive having a rubber polymer as a base polymer are preferably used as inexpensive and excellent in heat resistance.

The pressure-sensitive adhesive to constitute the pressure-sensitive adhesive layer may contain any other component as long as the effects of the present invention are not impaired. Examples of the other components that may be contained in the pressure-sensitive adhesive include an organic solvent, a high thermally conductive material, a flame retardant, a tackifier, a UV absorbent, an antioxidant, a preservative, an antifungal agent, a plasticizer, a defoaming agent, and a wettability improver.

The thickness of the pressure-sensitive adhesive layer is preferably 1 to 100 μm, more preferably 3 to 50 μm, and even more preferably 5 to 30 μm Falling within the range, the pressure-sensitive adhesive layer would have few influences on the heat radiation performance of the high thermally conductive layer.

### <Thermoelectric Conversion Module>

The thermoelectric conversion module for use in the present invention is so configured that P-type thermoelectric elements and N-type thermoelectric elements are alternately arranged to be adjacent to each other on one face of a film substrate, and are electrically connected to each other in series thereon. Further, from the viewpoint of interconnection stability and thermoelectric performance, the P-type thermoelectric elements and the N-type thermoelectric elements may be connected to each other via an electrode formed of a highly-electroconductive metal material or the like.

### <Film Substrate>

As the substrate of the thermoelectric conversion module for use in the present invention, a plastic film is used not having any influence on reduction in the electrical conductivity of the thermoelectric element and on increase in the thermal conductivity thereof. Above all, from the viewpoint that it is excellent in flexibility and that, even when a thin film of a thermoelectric semiconductor composition to be mentioned below is annealed, the substrate is not thermally deformed to maintain the performance of the thermoelectric element thereon and therefore has high heat resistance and high dimensional stability, a polyimide film, a polyamide film, a polyether imide film, a polyaramid film or a polyamideimide film is preferred; and from the viewpoint of high versatility thereof, a polyimide film is especially preferred.

The thickness of the substrate is, from the viewpoint of flexibility, heat resistance and dimensional stability, preferably 1 to 1,000 μm, more preferably 10 to 500 μm, and even more preferably 20 to 100 μm.

Also preferably, the decomposition temperature of the film is 300° C. or higher.

### <Thermoelectric Element>

Preferably, the thermoelectric element for use in the present invention is formed of a thermoelectric semiconductor composition containing thermoelectric semiconductor fine particles, a heat-resistant resin and one or both of an ionic liquid and an inorganic ionic compound, on a substrate.

### (Thermoelectric Semiconductor Fine Particles)

Preferably, the thermoelectric semiconductor fine particles for use in the thermoelectric element are prepared by grinding a thermoelectric semiconductor material into a predetermined size using a grinder or the like.

Not specifically limited, the material to constitute the P-type thermoelectric element and the N-type thermoelectric element for use in the present invention may be any material capable of generating a thermoelectromotive force when given a temperature difference, and examples thereof include a bismuth-tellurium-based thermoelectric semiconductor material such as a P-type bismuth telluride, and an N-type bismuth telluride; a telluride-based thermoelectric semiconductor material such as GeTe, and PbTe; an antimony-tellurium-based thermoelectric semiconductor material; a zinc-antimony-based thermoelectric semiconductor material such as ZnSb, Zn₃Sb₂, and Zn₄Sb₃; a silicon-germanium-based thermoelectric semiconductor material such as SiGe; a bismuth-selenide-based thermoelectric semiconductor material such as Bi₂Se₃; a silicide-based thermoelectric semiconductor material such as β-FeSi₂, CrSi₂, MnSi_{1.73}, and Mg₂Si; an oxide-based thermoelectric semiconductor material; a Heusler material such as FeVAl, FeVAlSi, and FeVTiAl; and a sulfide-based thermoelectric semiconductor material such as TiS₂.

Among these, the thermoelectric semiconductor material is preferably a bismuth-tellurium-based thermoelectric semiconductor material such as a P-type bismuth telluride or an N-type bismuth telluride.

The carrier of the P-type bismuth telluride is a hole and the Seebeck coefficient thereof is positive, for which, for example, preferably used is one represented by Bi_{X}Te₃Sb_{2-X}. In this case, X preferably satisfies 0<X≤0.8, more preferably 0.4≤X≤0.6. X being more than 0 and 0.8 or less is preferred since the Seebeck coefficient and the electrical conductivity of the material are large and the material can maintain the characteristics of a p-type thermoelectric conversion material.

The carrier of the N-type bismuth telluride is an electron and the Seebeck coefficient thereof is negative, for which, for example, preferably used is one represented by Bi₂Te_{3-Y}Se_{Y}. In this case, Y is preferably 0≤Y≤3 (when Y=0, Bi₂Te₃), and is more preferably 0.1<Y≤2.7. Y being 0 or more and 3 or less is preferred since the Seebeck coefficient and the electrical conductivity of the material are large and the material can maintain the characteristics of an n-type thermoelectric conversion material.

The blending amount of the thermoelectric semiconductor fine particles in the thermoelectric semiconductor composition is preferably 30 to 99% by mass. The amount is more preferably 50 to 96% by mass, even more preferably 70 to 95% by mass. The blending amount of the thermoelectric semiconductor fine particles falling within the above range is preferred since the Seebeck coefficient (absolute value of Peltier coefficient) is large, the electrical conductivity reduction can be prevented, only the thermal conductivity is lowered, and therefore the composition exhibits high-level thermoelectric performance and can form a film having a sufficient film strength and flexibility.

The average particle size of the thermoelectric semiconductor fine particles is preferably 10 nm to 200 μm, more preferably 10 nm to 30 μm, even more preferably 50 nm to 10 μm, and especially preferably 1 to 6 μm. Falling within the range, uniform dispersion is easy and electrical conductivity can be increased.

The method of producing the thermoelectric semiconductor fine particles by finely grinding the thermoelectric semiconductor material is not specifically defined, and the material may be ground into a predetermined size, using a known fine grinding mill or the like, such as a jet mill, a ball mill, a bead mill, a colloid mill, a conical mill, a disc mill, an edge mill, a flour mill, a hammer mill, a pellet mill, a whirly mill or a roller mill.

The average particle size of the thermoelectric semiconductor fine particles may be measured with a laser diffraction particle sizer (1064 Model, manufactured by CILAS), and the median value of the particle size distribution is taken as the average particle size.

Preferably, the thermoelectric semiconductor fine particles are annealed. (Hereinafter the annealing may be referred to as annealing treatment A.) The annealing treatment A increases the crystallinity of the thermoelectric semiconductor fine particles and further increases the Seebeck coefficient (absolute value of Peltier coefficient) of the thermoelectric conversion material since the surface oxide film of the thermoelectric semiconductor fine particles could be removed, therefore further increasing the figure of merit thereof. Not specifically defined, in order not to adversely affect the thermoelectric semiconductor fine particles, the annealing treatment A is preferably carried out in an inert gas atmosphere such as nitrogen or argon in which the gas flow rate is controlled or in a reducing gas atmosphere such as hydrogen in which also the gas flow rate is controlled, or in a vacuum condition, and is more preferably carried out in a mixed gas atmosphere of an inert gas and a reducing gas. Specific temperature conditions depend on the thermoelectric semiconductor fine particles to be used, but in general, it is desirable that the treatment is carried out at a temperature not higher than the melting point of the fine particles but falling between 100 and 1,500° C., for a few minutes to a few dozen hours.

### (Heat-Resistant Resin)

The heat-resistant resin for use in the present invention acts as a binder between the thermoelectric semiconductor fine particles and enhances the flexibility of the thermoelectric conversion material. The heat-resistant resin is not specifically defined. The heat-resistant resin for use herein is one that can maintain various physical properties thereof such as mechanical strength and thermal conductivity thereof as a resin without losing them in crystal growth of the thermoelectric semiconductor fine particles through annealing treatment of the thin film of the thermoelectric semiconductor composition.

Examples of the heat-resistant resin include a polyamide resin, a polyamideimide resin, a polyimide resin, a polyether imide resin, a polybenzoxazole resin, a polybenzimidazole resin, an epoxy resin, and a copolymer having a chemical structure of any of these resins. One alone or two or more kinds of the heat-resistant resins may be used either singly or as combined. Among these, from the viewpoint of having higher heat resistance and having no negative influence on crystal growth of thermoelectric semiconductor fine particles in a thin film, a polyamide resin, a polyamideimide resin, a polyimide resin, and an epoxy resin are preferred; and from the viewpoint of having excellent flexibility, a polyamide resin, a polyamideimide resin and a polyimide resin are more preferred. In the case where a polyimide film is used as the substrate, the heat-resistant resin is more preferably a polyimide resin from the viewpoint of the adhesiveness thereof to the polyimide film. In the present invention, a polyimide resin is a general term for polyimide and its precursor.

Preferably, the decomposition temperature of the heat-resistant resin is 300° C. or higher. When the decomposition temperature falls within the above range, the resin does not lose the function thereof as a binder and can maintain the flexibility of the thermoelectric conversion material even when the thin film of the thermoelectric semiconductor composition is annealed, as described below.

Preferably, the mass reduction in the heat-resistant resin at 300° C. in thermogravimetry (TG) is 10% or less, more preferably 5% or less, even more preferably 1% or less. When the mass reduction falls within the above range, the resin does not lose the function thereof as a binder and can maintain the flexibility of the thermoelectric conversion material even when the thin film of the thermoelectric semiconductor composition is annealed, as described below.

The blending amount of the heat-resistant resin in the thermoelectric semiconductor composition may be 0.1 to 40% by mass, preferably 0.5 to 20% by mass, and more preferably 1 to 20% by mass. The blending amount of the heat-resistant resin falling within the above range provides a film satisfying both good thermoelectric performance and film strength.

### (Ionic Liquid)

The ionic liquid for use in the present invention is a molten salt of a combination of a cation and an anion, which can exist as a liquid in a broad temperature range of −50 to 500° C. The ionic liquid is characterized in that it has an extremely low vapor pressure and is nonvolatile, has excellent thermal stability and electrochemical stability, has a low viscosity and has a high ionic conductivity, and therefore, serving as a conductive assistant, the ionic liquid can effectively prevent reduction in the electrical conductivity between thermoelectric semiconductor fine particles. In addition, the ionic liquid has high polarity based on the aprotic ionic structure thereof, and is excellent in compatibility with the heat-resistance resin, and therefore can make the thermoelectric conversion material has a uniform electrical conductivity.

The ionic liquid for use herein may be a known one or a commercially-available one. Examples thereof include those composed of a cation component of a nitrogen-containing cyclic cation compound such as pyridinium, pyrimidinium, pyrazolium, pyrrolidinium, piperidinium or imidazolium, or a derivative thereof, an amine-type cation such as tetraalkylammonium, or a derivative thereof, a phosphine-type cation such as phosphonium, trialkyl sulfonium or tetraalkyl phosphonium, or a derivative thereof, or a lithium cation or a derivative thereof, and an anion component of Cr, Br⁻, I⁻, AlCl₄⁻, Al₂Cl₇⁻, BF₄⁻, PF₆⁻, ClO₄⁻, NO₃⁻, CH₃COO⁻, CF₃COO⁻, CH₃SO₃⁻, CF₃SO₃⁻, (FSO₂)₂N⁻, (CF₃SO₂)₂N⁻, (CF₃SO₂)₃C⁻, AsF₆⁻, SbF₆⁻, NbF₆⁻, TaF₆⁻, F(HF)n⁻, (CN)₂N⁻, C₄F₉SO₃⁻, (C₂F₅SO₂)₂N⁻, C₃F₇COO⁻, or (CF₃SO₂)(CF₃CO)N⁻.

Among the above-mentioned ionic liquids, it is preferable that, from the viewpoint of enhancing high-temperature stability and compatibility between thermoelectric semiconductor fine particles and resin, and preventing reduction in the electrical conductivity between thermoelectric semiconductor fine particles, the cation component in the ionic liquid contains at least one selected from a pyridinium cation and a derivative, and an imidazolium cation and a derivative thereof.

Specific examples of the ionic liquid in which the cation component contains a pyridinium cation or a derivative thereof include 4-methyl-butylpyridinium chloride, 3-methyl-butylpyridinium chloride, 4-methyl-hexylpyridinium chloride, 3-methyl-hexylpyridinium chloride, 4-methyl-octylpyridinium chloride, 3-methyl-octylpyridinium chloride, 3,4-dimethyl-butylpyridinium chloride, 3,5-dimethyl-butylpyridinium chloride, 4-methyl-butylpyridinium tetrafluoroborate, 4-methyl-butylpyridinium hexafluorophosphate, 1-butyl-4-methylpyridinium bromide, and 1-butyl-4-methylpyridinium hexafluorophosphate. Among these, 1-butyl-4-methylpyridinium bromide and 1-butyl-4-methylpyridinium hexafluorophosphate are preferred.

Specific examples of the ionic liquid in which the cation component contains an imidazolium cation or a derivative thereof include [1-butyl-3-(2-hydroxyethyl)imidazolium bromide], [1-butyl-3-(2-hydroxyethyl)imidazolium tetrafluoroborate], 1-ethyl-3-methylimidazolium chloride, 1-ethyl-3-methylimidazolium bromide, 1-butyl-3-methylimidazolium chloride, 1-hexyl-3-methylimidazolium chloride, 1-octyl-3-methylimidazolium chloride, 1-decyl-3-methylimidazolium chloride, 1-decyl-3-methylimidazolium bromide, 1-dodecyl-3-methylimidazolium chloride, 1-tetradecyl-3-methylimidazolium chloride, 1-ethyl-3-methylimidazolium tetrafluoroborate, 1-butyl-3-methylimidazolium tetrafluoroborate, 1-hexyl-3-methylimidazolium tetrafluoroborate, 1-ethyl-3-methylimidazolium hexafluorophosphate, 1-butyl-3-methylimidazolium hexafluorophosphate, 1-methyl-3-butylimidazolium methylsulfate, and 1,3-dibutylimidazolium methylsulfate. Among these, [1-butyl-3-(2-hydroxyethyl)imidazolium bromide] and [1-butyl-3-(2-hydroxyethyl)imidazolium tetrafluoroborate] are preferred.

Preferably, the ionic liquid has an electrical conductivity of 10⁻⁷ S/cm or more. When the electrical conductivity falls within the above range, the ionic liquid can effectively prevent reduction in the electrical conductivity between thermoelectric semiconductor fine particles, serving as a conductive assistant.

Also preferably, the decomposition temperature of the ionic liquid is 300° C. or higher. When the decomposition temperature falls within the above range, the ionic liquid can still maintain the effect thereof as a conductive assistant even when the thin film of the thermoelectric semiconductor composition is annealed, as described below.

Preferably, the mass reduction in the ionic liquid at 300° C. in thermogravimetry (TG) is 10% or less, more preferably 5% or less, even more preferably 1% or less. When the mass reduction falls within the above range, the ionic liquid can still maintain the effect thereof as a conductive assistant even when the thin film of the thermoelectric semiconductor composition is annealed, as described below.

The blending amount of the ionic liquid in the thermoelectric semiconductor composition is preferably 0.01 to 50% by mass, more preferably 0.5 to 30% by mass, even more preferably 1.0 to 20% by mass. The blending amount of the ionic liquid falling within the above range provides a film capable of effectively preventing electrical conductivity reduction and having high electroconductive performance.

### (Inorganic Ionic Compound)

The inorganic ionic compound for use in the present invention is a compound composed of at least a cation and an anion. The inorganic ionic compound exists as a solid in a broad temperature range of 400 to 900° C. and is characterized by having a high ionic conductivity, and therefore, serving as a conductive assistant, the compound can prevent reduction in the electrical conductivity between thermoelectric semiconductor fine particles.

A metal cation is used as the cation.

Examples of the metal cation include an alkali metal cation, an alkaline earth metal cation, a typical metal cation and a transition metal cation, and an alkali metal cation or an alkaline earth metal cation is more preferred.

Examples of the alkali metal cation include Li⁺, Na⁺, K⁺, Rb⁺, Cs⁺ and Fr⁺.

Examples of the alkaline earth metal cation include Mg²⁺, Ca²⁺, Sr²⁺ and Ba²⁺.

Examples of the anion include F⁻, Cl⁻, Br⁻, I⁻, OH⁻, CN⁻, NO₃⁻, NO₂⁻, ClO⁻, ClO₂⁻, ClO₃⁻, ClO₄⁻, CrO₄²⁻, HSO₄⁻, SCN⁻, BF₄⁻, and PF₆⁻.

As the inorganic ionic compound, known or commercially-available ones can be used. Examples thereof include those composed of a cation component such as a potassium cation, a sodium cation or a lithium cation, and an anion component, e.g., a chloride ion such as Cl⁻, AlCl₄⁻, Al₂Cl₇⁻, or ClO₄⁻, a bromide ion such as Br⁻, an iodide ion such as I⁻, a fluoride ion such as BF₄⁻ or PF₆⁻, a halide anion such as F(HF)ₙ⁻, or any other anion component such as NO₃⁻, OH⁻, or CN⁻.

Among the above-mentioned inorganic ionic compounds, those having at least one selected from potassium, sodium and lithium as the cation component are preferred from the viewpoint of securing high-temperature stability and compatibility between thermoelectric semiconductor fine particles and resin, and from the viewpoint of preventing reduction in the electrical conductivity between thermoelectric semiconductor fine particles. Also preferably, the anion component of the inorganic ionic compound contains a halide anion, more preferably at least one selected from Cl⁻, Br⁻ and I⁻.

Specific examples of the inorganic ionic compound having a potassium cation as the cation component include KBr, KI, KCl, KF, KOH, and K₂CO₃. Among these, KBr and KI are preferred.

Specific examples of the inorganic ionic compound having a sodium cation as the cation component include NaBr, NaI, NaOH, NaF, and Na₂CO₃. Among these, NaBr and NaI are preferred.

Specific examples of the inorganic ionic compound having a lithium cation as the cation component include LiF, LiOH, and LiNO₃. Among these, LiF and LiOH are preferred.

Preferably, the above inorganic ionic compound has an electrical conductivity of 10⁻⁷ S/cm or more, more preferably 10⁻⁶ S/cm or more. When the electrical conductivity falls within the above range, the inorganic ionic compound serving as a conductive assistant can effectively prevent reduction in the electrical conductivity between the thermoelectric semiconductor fine particles.

Also preferably, the decomposition temperature of the inorganic ionic compound is 400° C. or higher. When the decomposition temperature falls within the above range, the inorganic ionic compound can still maintain the effect thereof as a conductive assistant even when the thin film of the thermoelectric semiconductor composition is annealed, as described below.

Preferably, the mass reduction in the inorganic ionic compound at 400° C. in thermogravimetry (TG) is 10% or less, more preferably 5% or less, even more preferably 1% or less. When the mass reduction falls within the above range, the inorganic ionic compound can still maintain the effect thereof as a conductive assistant even when the thin film of the thermoelectric semiconductor composition is annealed, as described below.

The blending amount of the inorganic ionic compound in the thermoelectric semiconductor composition is preferably 0.01 to 50% by mass, more preferably 0.5 to 30% by mass, even more preferably 1.0 to 10% by mass. When the blending amount of the inorganic ionic compound falls within the above range, the electrical conductivity can be effectively prevented from lowering and, as a result, a film having a high thermoelectric performance level can be realized.

In the case where the inorganic ionic compound and the ionic liquid are used together, the total content of the inorganic ionic compound and the ionic liquid in the thermoelectric semiconductor composition is preferably 0.01 to 50% by mass, more preferably 0.5 to 30% by mass, even more preferably 1.0 to 10% by mass.

The thickness of the P-type thermoelectric element and the N-type thermoelectric element is not specifically limited, and the two may have the same thickness or have a different thickness. From the viewpoint of imparting a large temperature difference to the in-plane direction of the thermoelectric conversion module, preferably, the two have the same thickness. The thickness of the P-type thermoelectric element or the N-type thermoelectric element is preferably 0.1 to 100 μm, more preferably 1 to 50 μm.

When the maximum length of the high thermally conductive layer in the direction parallel to the direction in which the P-type thermoelectric elements and the N-type thermoelectric elements are alternately arranged to be adjacent to each other on the plane of the thermoelectric conversion module is represented by L, and the minimum radius of curvature in terms of a face on which the thermoelectric conversion module is to be mounted is represented by R, preferably, L/R≤0.04. More preferably, L/R≤0.03. When the requirement is satisfied, the device can maintain flexibility in the direction parallel to the direction in which the P-type thermoelectric elements and the N-type thermoelectric elements are alternately arranged to be adjacent to each other. Here, for the minimum radius of curvature, an electric resistance value between output extraction electrodes of the flexible thermoelectric conversion device is measured before and after the flexible thermoelectric conversion device is mounted on a curved face having a known radius of curvature, and a minimum value of the radius of curvature at which the electric resistance increment is 20% or less is designated as the minimum radius of curvature.

### [Method for Producing Flexible Thermoelectric Conversion Device]

A method for producing the flexible thermoelectric conversion device of the present invention is a method for producing a flexible thermoelectric conversion device which includes a thermoelectric conversion module having P-type thermoelectric elements and N-type thermoelectric elements alternately arranged to be adjacent to each other on one face of a film substrate, and a high thermally conductive layer composed of a high thermally conductive material in a part on at least the other face of the film substrate among both faces of the thermoelectric conversion module, in which the thermal conductivity of the high thermally conductive layer is 5 to 500 (W/m·K),

the method including a step of forming P-type thermoelectric elements and N-type thermoelectric elements on one face of the film substrate, and a step of forming a high thermally conductive layer on a part on the other face of the film substrate. Hereinunder the steps that the invention includes are described sequentially.

### <Thermoelectric Element Forming Step>

The thermoelectric element for use in the present invention is formed of the above-mentioned thermoelectric semiconductor composition. A method for applying the thermoelectric semiconductor composition to the above-mentioned film substrate is not specifically defined, for which employable is any known method of screen printing, flexographic printing, gravure printing, spin coating, dip coating, die coating, spray coating, bar coating, or doctor blade coating. In the case where the coating film is pattern-like formed, preferably employed is screen printing or slot die coating that realizes patterning in a simplified manner using a screen having a desired pattern.

Next, the resultant coating film is dried to give a thin film. As the drying method, employable is any known drying method such as hot air drying, hot roll drying, or IR radiation. The heating temperature is generally from 80 to 150° C., and the heating time is generally from a few seconds to several tens minutes though it varies depending on the heating method.

In the case where a solvent is used in preparing the thermoelectric semiconductor composition, the heating temperature is not specifically defined so far as it falls within a temperature range capable of removing the used solvent through vaporization.

### <High Thermally Conductive Layer Laminating Step>

This is a step of laminating a high thermally conductive layer composed of a high thermally conductive material on the thermoelectric conversion module.

A method for forming a high thermally conductive layer is as described hereinabove. In the present invention, preferably, the high thermally conductive layer is previously patterned through photolithography or the like and formed on a face of the thermoelectric conversion module via a pressure-sensitive adhesive layer. The high thermally conductive material can be appropriately selected from the viewpoint of the constituent material and the processability of the thermoelectric conversion module.

### <Pressure-Sensitive Adhesive Layer Laminating Step>

The production method for the flexible thermoelectric conversion device further includes a pressure-sensitive adhesive layer laminating step. The pressure-sensitive adhesive layer laminating step is a step of laminating a pressure-sensitive adhesive layer on a face of the thermoelectric conversion module.

The pressure-sensitive adhesive layer may be formed according to any known method. The layer may be directly formed on the thermoelectric conversion module, or a pressure-sensitive adhesive layer previously formed on a release sheet may be adhered to a thermoelectric conversion module and transferred thereto to thereby form the pressure-sensitive adhesive layer on the thermoelectric conversion module.

According to the production method of the present invention, a flexible thermoelectric conversion device can be produced in a simplified method, and the device can be efficiently given a great temperature difference in the in-plane direction inside the thermoelectric conversion module therein.

### EXAMPLES

Next, the present invention is described in more detail by reference to Examples, but it should be construed that the present invention is not limited to these Examples at all.

The thermoelectric conversion devices produced in Examples and Comparative Examples were evaluated in point of the output and the flexibility thereof, according to the methods mentioned below.

### (a) Output Voltage Evaluation

While one side of the produced thermoelectric conversion device was kept heated on a hot plate, the other side thereof was cooled to 5° C. with a water-cooled heatsink to thereby impart a temperature difference of 35, 45 or 55° to the flexible thermoelectric conversion device, and using a Digital Hightester (Model 3801-50, manufactured by Hioki E.E. Corporation), the voltage value at each temperature difference was measured.

### (b) Flexibility Evaluation

(b-1) The flexibility of the produced thermoelectric conversion device was evaluated in a cylindrical mandrel method according to JIS K 5600-5-1:1999 in which the mandrel diameter was ϕ 80 mm. Before and after the cylindrical mandrel test, the thermoelectric conversion device was checked for the appearance and the thermoelectric performance thereof, and the flexibility of the device was evaluated according to the following criteria.

A: Before and after the test, there was found no change in the appearance and the output of the thermoelectric conversion device.

B: Before and after the test, there was found no change in the appearance of the thermoelectric conversion device, and the output reduction was less than 30%.

C: After the test, there was found a breakage such as crack in the thermoelectric conversion device, and the output reduction was 30% or more.

(b-2) Further, the device was subjected to the following test, which is severer than the test (b-1).

Specifically, the produced thermoelectric conversion device was mounted on a curved face having a known radius of curvature, and before and after the mounting, the electric resistance value between the extraction electrodes of the flexible thermoelectric conversion device was measured using a Digital Hightester (Model 3801-50, manufactured by Hioki E.E. Corporation). A minimum radius of curvature of the curved face on which the increment was 20% or less was determined, and the flexibility of the device was evaluated according to the following criteria.

A: Before and after the measurement, there was found no change in the appearance of the thermoelectric conversion device, and the minimum radius of curvature was 35 mm or less.

B: Before and after the measurement, there was found some change in the appearance of the thermoelectric conversion device, or the minimum radius of curvature was more than 35 mm.

(b-3) On a flat face of the thermoelectric conversion module, the maximum length of the high thermally conductive layer in a direction parallel to the direction of the P-type thermoelectric elements and the N-type thermoelectric elements alternately arranged to be adjacent to each other was referred to as L, and the minimum radius of curvature in terms of a face on which the thermoelectric conversion module was to be mounted was referred to as R, and L/R was calculated.

### (c) Measurement of Thermal Conductivity of High Thermally Conductive Material

Using a thermal conductivity meter (HC-110, manufactured by EKO Japan Co., Ltd.), the thermal conductivity of the high thermally conductive material was measured.

### <Production of Thermoelectric Conversion Module>

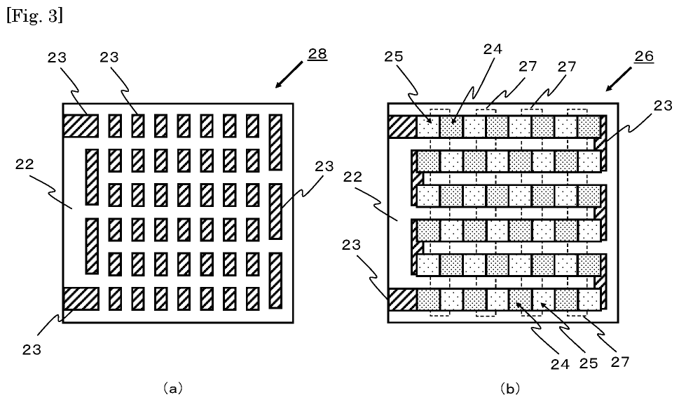

FIG. 3 is a plan view showing a configuration of a thermoelectric conversion module used in Examples; (a) shows a configuration of electrodes of a film electrode substrate, and (b) shows a configuration of P-type and N-type thermoelectric elements formed on the film electrode substrate.

Onto a film electrode substrate 28 having a pattern of copper electrodes 23 (thickness: 1.5 μm) on a polyimide film (Kapton 200H, manufactured by DuPont-Toray Co., Ltd., 100 mm×100 mm, thickness: 50 μm) substrate 22, coating liquids (P) and (N) to be mentioned below were applied to form P-type thermoelectric elements 25 and N-type thermoelectric elements 24 arranged alternately to be adjacent to each other, thereby producing a thermoelectric conversion module 26 having, as formed thereon, 380 pairs of P-type thermoelectric elements and N-type thermoelectric elements in a size of 1 mm×6 mm. In FIG. 3, on the back side of the thermoelectric conversion module 26, a high thermally conductive layer 27 (dotted line) to be mentioned below can be arranged via a pressure-sensitive adhesive layer (a high thermally conductive layer to be arranged on the surface side of the thermoelectric conversion module via a pressure-sensitive adhesive layer is not shown).

### (Method for Producing Thermoelectric Semiconductor Fine Particles)

Using a planetary ball mill (Premium Line P-7, manufactured by Fritsch Japan Co., Ltd.), a p-type bismuth telluride Bi_{0.4}Te₃Sb_{1.6} (manufactured by Kojundo Chemical Laboratory Co., Ltd., particle size: 180 μm) of a bismuth-tellurium-based thermoelectric semiconductor material was ground in a nitrogen gas atmosphere to give thermoelectric semiconductor fine particles T1 having an average particle size of 1.2 μm. The resultant ground thermoelectric semiconductor fine particles were analyzed for particle size distribution, using a laser diffraction particle size analyzer (Mastersizer 3000, manufactured by Malvern Panalytical Ltd.).

In addition, an n-type bismuth telluride Bi₂Te₃ (manufactured by Kojundo Chemical Laboratory Co., Ltd., particle size: 180 μm) of a bismuth-tellurium-based thermoelectric semiconductor material was ground in the same manner as above to prepare thermoelectric semiconductor fine particles T2 having an average particle size of 1.4 μm.

### (Production of Thermoelectric Semiconductor Composition)

### Coating Liquid (P)

90 parts by mass of the resultant fine particles T1 of a P-type bismuth-tellurium-based thermoelectric semiconductor material, 5 parts by mass of a heat-resistant resin, polyamic acid of a polyimide precursor (manufactured by Sigma Aldrich Corporation, poly(pyromellitic dianhydride-co-4,4′-oxydianiline)amide acid solution, solvent: N-methylpyrrolidone, solid concentration: 15% by mass) and 5 parts by mass of an ionic liquid, [1-butyl-3-(2-hydroxyethyl)imidazolium bromide] were mixed and dispersed to prepare a coating liquid (P) of a thermoelectric semiconductor composition.

### Coating Liquid (N)

90 parts by mass of the resultant fine particles T2 of an N-type bismuth-tellurium-based thermoelectric semiconductor material, 5 parts by mass of a heat-resistant resin, polyamic acid of a polyimide precursor (manufactured by Sigma Aldrich Corporation, poly(pyromellitic dianhydride-co-4,4′-oxydianiline)amide acid solution, solvent: N-methylpyrrolidone, solid concentration: 15% by mass) and 5 parts by mass of an ionic liquid, [1-butyl-3-(2-hydroxyethyl)imidazolium bromide] were mixed and dispersed to prepare a coating liquid (N) of a thermoelectric semiconductor composition.

### (Production of Thermoelectric Element)

The coating liquid (P) prepared in the above was applied onto the above-mentioned polyimide film according to a screen printing method, and dried in an argon atmosphere at a temperature of 150° C. for 10 minutes to form a thin film having a thickness of 50 μm. Next, similarly, the coating liquid (N) prepared in the above was applied to the above-mentioned polyimide film, and dried in an argon atmosphere at a temperature of 150° C. for 10 minutes to form a thin film having a thickness of 50 μm.

Further, the resultant thin films were heated in an atmosphere of a mixed gas of hydrogen and argon (hydrogen/argon=3 vol %/97 vol %) at a heating rate of 5 K/min, and kept at 400° C. for 1 hour for annealing after the thin film formation to grow the crystals of the fine particles of the thermoelectric semiconductor material, thereby producing P-type thermoelectric elements and N-type thermoelectric elements.

### Example 1

### (A) Production of Flexible Thermoelectric Conversion Device

On both sides of the produced thermoelectric conversion module, and via a pressure-sensitive adhesive layer (produced by Lintec Corporation, trade name: P1069, thickness: 22 μm) therebetween, a stripe-like, high thermally conductive layer (C1020, thickness 100 μm, width: 1 mm, length: 100 mm, spacing: 1 mm, thermal conductivity: 398 (W/m·K)) composed of a high thermally conductive material was so formed as to be alternating with each other on the top and the bottom of the site at which the P-type thermoelectric conversion material and the N-type thermoelectric conversion material were adjacent to each other, as shown in FIG. 2, thereby producing a flexible thermoelectric conversion device.

### Example 2

A flexible thermoelectric conversion device was produced in the same manner as in Example 1, except that the thickness of the high thermally conductive layer was changed to 250 μm

### Example 3

A flexible thermoelectric conversion device was produced in the same manner as in Example 1, except that the thickness of the high thermally conductive layer was changed to 500 μm.

### Example 4

A flexible thermoelectric conversion device was produced in the same manner as in Example 1, except that the high thermally conductive material was changed to SUS304 (thermal conductivity: 16 (W/m·K)).

### Comparative Example 1

A flexible thermoelectric conversion device was produced in the same manner as in Example 1, except that a low thermally conductive material, polyimide (thermal conductivity: 0.16 (W/m·K)) was arranged as a low thermally conductive layer in the space between the high thermally conductive layers.

### Comparative Example 2

A flexible thermoelectric conversion device was produced in the same manner as in Example 1, except that the high thermally conductive material was changed to a cured product of a silver paste (manufactured by Noritake Company Limited, trade name NP-2910B2, silver solid content: 70 to 80% by mass) (thermal conductivity 4.0 (W/m·K)).

The flexible thermoelectric conversion devices obtained in Examples 1 to 4 and Comparative Examples 1 and 2 were evaluated in point of output and flexibility. The evaluation results are shown in Table 1.

TABLE 1

| | High Thermally | | | Low Thermally | | | | | | | | | |
|---|---|---|---|---|---|---|---|---|---|---|---|---|---|
| | Conductive Layer | | | Conductive Layer | | | | | | Flexibility Evaluation | | | |
| | | Thermal | | | Thermal | | Output Voltage | | | | Minimum | | |
| | | Conduc- | | | Conduc- | | Evaluation (V) | | | | Radius of | | |
| | | tivity | Thickness | | tivity | Thickness | ΔT | ΔT | ΔT | Cylindrical | Curvature | | |
| | Material | (W/m · K) | (gm) | Material | (W/m · K) | (gm) | 35(° C.) | 45(° C.) | 55(° C.) | Mandrel | (mm) | | L/R |
| Example 1 | C1020 | 398 | 100 | — | — | — | 0.86 | 1.12 | 1.42 | A | 30 | A | 0.033 |
| Example 2 | C1020 | 398 | 250 | — | — | — | 1.05 | 1.43 | 1.78 | A | 30 | A | 0.033 |
| Example 3 | C1020 | 398 | 500 | — | — | — | 1.05 | 1.38 | 1.78 | A | 30 | A | 0.033 |
| Example 4 | SUS304 | 16 | 100 | — | — | — | 0.81 | 1.08 | 1.36 | A | 30 | A | 0.033 |
| Comparative | C1020 | 398 | 100 | polyimide | 0.16 | 84 | 0.59 | 0.77 | 0.97 | C | >40 | B | <0.025 |
| Example 1 | | | | | | | | | | | | | |
| Comparative | Ag Paste | 4 | 100 | — | — | — | 0.62 | 0.86 | 1.08 | A | 30 | A | 0.033 |
| Example 2 | | | | | | | | | | | | | |

L: maximum length of high thermally conductive layer
R: minimum radius of curvature in terms of a face on which the thermoelectric conversion module is to be mounted

It is known that Example 1 had a high output and kept flexibility, as compared with Comparative Example 1 having the same configuration except that a low thermally conductive layer was arranged in the space between the high thermally conductive layers. It is also known that the output in Examples 1 and 4 was higher by 30 to 40% or so than that in Comparative Example 2 having a low thermal conductivity.

### INDUSTRIAL APPLICABILITY

The flexible thermoelectric conversion device of the present invention is efficiently given a temperature difference in the in-plane direction of the thermoelectric conversion module therein where P-type thermoelectric elements and N-type thermoelectric elements are alternately electrically connected in series to each other via electrodes therebetween. Accordingly, the device of the present invention enables high power generation and, as compared with already-existing devices, the number of the thermoelectric conversion modules to be arranged therein may be reduced, therefore resulting in down-sizing and cost reduction of the device. Another advantage of the flexible thermoelectric conversion device of the present invention is that the device can be installed even in waste heat sources or heat dissipators having an uneven face, that is, the device is not limited in point of the installation site thereof.

### REFERENCE SIGNS LIST

1: Flexible Thermoelectric Conversion Device
2: Film Substrate
3: Electrode
4: N-type Thermoelectric Element
5: P-type Thermoelectric Element
6: Thermoelectric Conversion Module
7: High Thermally Conductive Layer
11: Flexible Thermoelectric Conversion Device
12: Film Substrate
13: Electrode
14: N-type Thermoelectric Element
15: P-type Thermoelectric Element
16: Thermoelectric Conversion Module
17a, 17b: High Thermally Conductive Layer
18a, 18b: Pressure-Sensitive Adhesive Layer
22: Polyimide Film Substrate
23: Copper Electrode
24: N-type Thermoelectric Element
25: P-type Thermoelectric Element
26: Thermoelectric Conversion Module
27: High Thermally Conductive Layer
28: Film Electrode Substrate

1. A flexible thermoelectric conversion device, comprising:
a thermoelectric conversion module comprising a P-type thermoelectric element and an N-type thermoelectric element, wherein the P-type thermoelectric element and the N-type thermoelectric element are alternately arranged to be adjacent to each other on one face of a film substrate; and
a first high thermally conductive layer composed of a first high thermally conductive material in a part of a position on a first face of the thermoelectric conversion module, which is on the side of the other face of the film substrate,
wherein a thermal conductivity of the first high thermally conductive layer is from 5 to 500 (W/m·K).

2. The flexible thermoelectric conversion device according to claim 1, further comprising:
a second high thermally conductive layer composed of a second high thermally conductive material in a part of a position on a second face of the thermoelectric conversion module opposite to the first face of the thermoelectric conversion module.

3. The flexible thermoelectric conversion device according to claim 1, wherein the first high thermally conductive layer is arranged via a pressure-sensitive adhesive layer.

4. The flexible thermoelectric conversion device according to claim 1, wherein a thickness of the first high thermally conductive layer is from 40 to 550 μm.

5. The flexible thermoelectric conversion device according to claim 1, wherein the first high thermally conductive material is copper or stainless.

6. The flexible thermoelectric conversion device according to claim 1, wherein a proportion of the first high thermally conductive layer positioned is from 0.30 to 0.70 relative to an entire width in a serial direction occupied by a pair of the P-type thermoelectric element and the N-type thermoelectric element.

7. The flexible thermoelectric conversion device according to claim 1, which satisfies L/R≤0.04, where L represents a maximum length of the first high thermally conductive layer in a direction parallel to a direction of the P-type thermoelectric element and the N-type thermoelectric element; and R represents a minimum radius of curvature in terms of a face on which the thermoelectric conversion module is to be mounted, with the proviso that a minimum radius of curvature is determined as follows: an electric resistance value between output extraction electrodes of the flexible thermoelectric conversion device is measured before and after the flexible thermoelectric conversion device is mounted on a curved face having a known radius of curvature, and a minimum value of the radius of curvature at which the electric resistance increment is 20% or less is designated as the minimum radius of curvature.

8. A method for producing a flexible thermoelectric conversion device which comprises a thermoelectric conversion module comprising a P-type thermoelectric element and a N-type thermoelectric element alternately arranged on one face of a film substrate to be adjacent to each other, and a high thermally conductive layer composed of a high thermally conductive material in a part on at least the other face of the film substrate, in which a thermal conductivity of the high thermally conductive layer is from 5 to 500 (W/m·K);
the method comprising:
forming the P-type thermoelectric element and the N-type thermoelectric element on one face of the film substrate, and
forming a high thermally conductive layer on a part on the other face of the film substrate.

9. The flexible thermoelectric conversion device according to claim 2, wherein the second high thermally conductive layer is arranged via a pressure-sensitive adhesive layer.

10. The flexible thermoelectric conversion device according to claim 2, wherein a thickness of the second high thermally conductive layer is from 40 to 550 μm.

11. The flexible thermoelectric conversion device according to claim 2, wherein the second high thermally conductive material is copper or stainless.
